(19) United States
(12) Patent Application Publication
(10) Pub. No.: US 2025/0210314 A1
(43) Pub. Date: Jun. 26, 2025

(54) PLASMA INJECTION CONFIGURATIONS FOR PROCESSING CHAMBERS, AND RELATED APPARATUS, CHAMBER KITS, AND METHODS

(71) Applicant: Applied Materials, Inc., Santa Clara, CA (US)

(72) Inventors: Ala MORADIAN, Sunnyvale, CA (US); Zuoming ZHU, Sunnyvale, CA (US); Saurabh CHOPRA, Santa Clara, CA (US); Ananth Nuggehalli BHOJ, Santa Clara, CA (US); Prashanth KOTHNUR, San Jose, CA (US); Phillip STOUT, Santa Clara, CA (US)

(21) Appl. No.: 18/391,210

(22) Filed: Dec. 20, 2023

(51) Int. Cl. H01J 37/32

(52) U.S. Cl. CPC H01J 37/32449; H01J 37/32119; H01J 37/32174; H01J 37/32522; H01J 37/32715; H01J 37/32834; H01J 37/32862; H01J 37/32733; H01J 2237/3321; H01J 2237/3323; H01J 2237/335

(57) ABSTRACT

The present disclosure relates to plasma injection configurations for process chambers, and related apparatus, chamber kits, and methods for semiconductor manufacturing. In one or more embodiments, a processing chamber applicable for use in semiconductor manufacturing includes one or more sidewalls, a window at least partially defining a processing volume, a substrate support disposed in the processing volume, and one or more heat sources operable to heat the processing volume. The processing chamber includes a flow housing disposed at least partially outwardly of the one or more sidewalls, and one or more radio frequency (RF) coils disposed at least partially around the flow housing.

### BACKGROUND

### Field

The present disclosure relates to plasma injection configurations for process chambers, and related apparatus, chamber kits, and methods for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

However, operations (such as epitaxial deposition operations) can be long, expensive, and inefficient, and can have limited capacity and throughput. Operations can also be limited with respect to application modularity. Moreover, hardware can involve relatively large dimensions that occupy higher footprints in manufacturing facilities. Additionally, processing can involve non-uniformities, which can involve hindered device performance and/or reduced throughput. For example, activation of gases can be limited and/or can involve non-uniform activation, which can cause limited and/or non-uniform film growth and/or dopant concentration. The activation of gases can be limited, for example, at relatively low processing temperatures for device production (such as complementary field-effect transistor (CFET) devices). Moreover, relatively higher processing temperatures can involve unintended dopant diffusion and/or hindered device performance.

Therefore, a need exists for improved apparatuses and methods in semiconductor processing.

### SUMMARY

The present disclosure relates to plasma injection configurations for process chambers, and related apparatus, chamber kits, and methods for semiconductor manufacturing.

In one or more embodiments, a processing chamber applicable for use in semiconductor manufacturing includes one or more sidewalls, a window at least partially defining a processing volume, and a substrate support disposed in the processing volume. The processing chamber includes one or more heat sources operable to heat the processing volume, a flow housing disposed at least partially outwardly of the one or more sidewalls, and one or more radio frequency (RF) coils disposed at least partially around the flow housing.

In one or more embodiments, a chamber kit applicable for semiconductor manufacturing includes a substrate support having a first outer dimension, a first plate having a second outer dimension that is larger than the first outer dimension, and a second plate. The second plate has a third outer dimension that is larger than the second outer dimension.

In one or more embodiments, a method of substrate processing includes heating a substrate on a substrate support to a target temperature, flowing a first process gas to a first flow level aligning with the substrate, and flowing a plasma to the first flow level.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2A is a schematic partial top cross-sectional view of a processing chamber, according to one or more embodiments.

FIG. 2B is a schematic side cross-sectional view of a flow housing assembly, according to one or more embodiments.

FIGS. 3-5 are a schematic side cross-sectional view of a processing chamber, according to one or more embodiments.

FIG. 6 is a schematic perspective view of a side of a processing chamber, according to one or more embodiments.

FIG. 7 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to plasma injection configurations for process chambers, and related apparatus, chamber kits, and methods for semiconductor manufacturing. In one or more embodiments, a plurality of levels are used for gas and plasma injection. In one or more embodiments, the plasma is used to activate gases in relatively low temperature epitaxial deposition operations.

The disclosure contemplates that terms such as “couples,” “coupling,” “couple,” and “coupled” may include but are not limited to bonding, embedding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

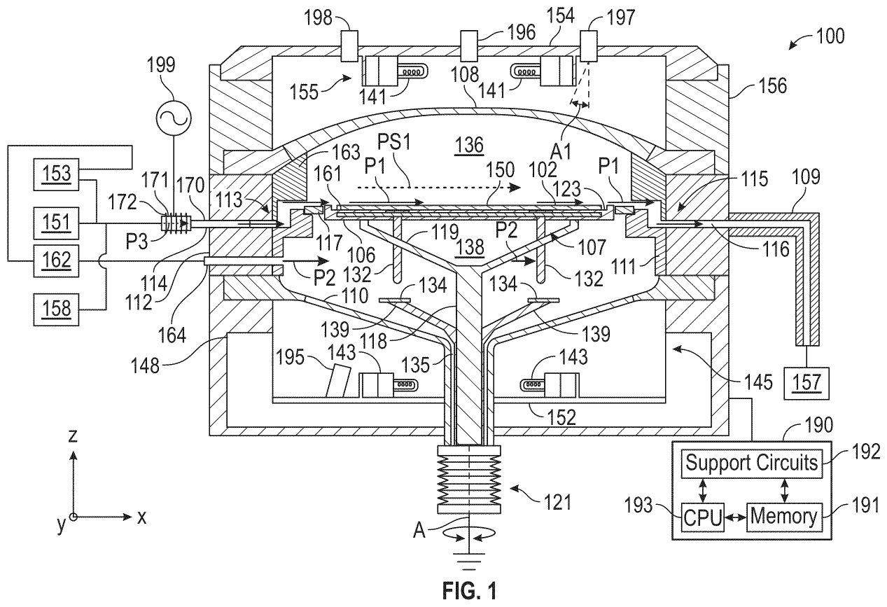

FIG. 1 is a schematic side cross-sectional view of a processing chamber 100, according to one or more embodiments. The processing chamber 100 is a deposition chamber. In one or more embodiments the processing chamber 100 is applicable for semiconductor manufacturing. In one or more embodiments, the processing chamber 100 is an epitaxial deposition chamber. The processing chamber 100 is utilized to grow an epitaxial film on a substrate 102, and the processing chamber 100 is used to supply a plasma for plasma operations (such as plasma-assisted film deposition, supply of ions into the substrate 102, pre-cleaning of the substrate 102, etching of the substrate 102, and/or cleaning of the processing chamber 100). In one or more embodiments, the processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, a plate 108, one or more heat sources 141, 143, and a window 110 (e.g., a lower window, for example a lower dome). The window 110 is formed of an energy transmissive material, such as transparent quartz. In one or more embodiments, the plate 108 is a window, such as an upper window, for example an upper dome. In such an embodiment, the plate 108 can be formed of an energy transmissive material, such as transparent quartz. The one or more heat sources 141, 143 include a plurality of lower heat sources 143 operable to heat a processing volume 136 from one side of the substrate 102 (e.g., from below the substrate 102). In one or more embodiments, the one or more heat sources 141, 143 include a plurality of upper heat sources 141 operable to heat the processing volume 136 from a second side of the substrate 102 (e.g., from above the substrate 102). The chamber body and the plate 108 at least partially define the processing volume 136. In one or more embodiments, the heat sources 141, 143 include lamps (such as halogen lamps or UV lamps). The present disclosure contemplates that other heat sources may be used (in addition to or in place of the lamps) for the various heat sources described herein. For example, resistive heaters, microwave powered heaters, light emitting diodes (LEDs), lasers (e.g., laser diodes), and/or or any other suitable heat source singly or in combination may be used for the various heat sources described herein.

The substrate support 106 is disposed in the processing volume 136 and between the plate 108 and the window 110. The substrate support 106 is disposed between the one or more heat sources 141, 143, and the substrate support 106 supports the substrate 102. The plate 108 is disposed between the substrate support 106 and a lid 154 of the processing chamber 100. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The upper heat sources are disposed between the lid 154 and the plate 108. The plurality of lower heat sources 143 are disposed between the window 110 and a floor 152. The plurality of lower heat sources 143 form a portion of a lower heat source module 145.

The processing volume 136 and a purge volume 138 are between the plate 108 and the window 110. The processing volume 136 and the purge volume 138 are part of an internal volume of the processing chamber 100. One or more liners 111, 163 are disposed inwardly of the chamber body.

The substrate support 106 includes a top surface on which the substrate 102 is disposed. The substrate support 106 is coupled to a shaft 118. In one or more embodiments, the substrate support 106 is coupled to the shaft 118 through one or more arms 119 coupled to the shaft 118. The shaft 118 is coupled to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 are part of an inject portion 113 of the chamber body, and the one or more gas exhaust outlets 116 are part of an exhaust portion 115 of the chamber body. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The pre-heat ring 117 can include a complete ring or one or more ring segments. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (Cl). In one or more embodiments, the one or more process gases P1 include silicon phosphide (SiP) and/or phosphine (PH₃), and the one or more cleaning gases include hydrochloric acid (HCl).

One or more plasma gas sources 158 are also fluidly connected to the gas inlet(s) 114. The one or more plasma gas sources 158 supply one or more plasma precursor gases that can be ignited into a plasma. A flow housing 171 is disposed at least partially outward of the flow module 112 and is fluidly connected to the flow module 112 through one or more flow channels 170 disposed between the flow housing 171 and the gas inlet 114. One or more radio frequency (RF) coils 172 is disposed at least partially around the flow housing 171. For example, the one or more RF coils 172 can be wound around the flow housing 171. As a plasma gas P3 flows from the plasma gas source 158 and through the flow housing 171, the one or more RF coils ignite the plasma gas P3 into a plasma PS1 which then flows through the one or more flow channels 170 and into the gas inlet 114. The one or more flow channels 170 can be formed, for example, in one or more gas boxes. RF current flows through the one or more RF coils while the gas P3 flows, which applies a voltage across the gas P3 to ignite the gas P3 into the plasma PS1. The present disclosure contemplates that an ion filter can be positioned such that the ion filter filters ions from the plasma PS1 prior to the plasma PS1 flowing over the substrate 102. The ion filter can include a conductive material including, for example, silicon carbide (SiC), molybdenum, tungsten, stainless steel, and/or aluminum (such as anodized aluminum). The ion filter can include an ion blocker plate. The one or more plasma gases P3 supplied using the one or more plasma gas sources 158 can include one or more precursor gases to generate plasma such as Xenon (Xe₂), Neon (Ne₂), Helium (He₂) Fluorine (F₂), Krypton (Kr2), and/or any mixtures of the thereof (such as Krypton Fluoride (KrF). In one or more embodiments, the plasma gas P3 includes one or more silicon-containing gases (e.g., silane, dichlorosilane (DCS), trichlorosilane (TCS), disilane (DS), and/or tetraclorosilane) mixed with a carrier gas (e.g., argon, hydrogen, and/or helium). In one or more embodiments, the plasma gas P3 includes one or more dopant gases, such as germane, diborane, and/or phosphorous. Other gases are contemplated for the plasma gas P3. Other precursor gases are contemplated to generate the plasma.

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111.

During a deposition operation (e.g., an epitaxial growth operation), the one or more process gases P1 flow through the one or more gas inlets 114, through the one or more gaps, and into the processing volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The present disclosure contemplates that the plasma PS1 and the one or more process gases P1 can flow simultaneously and/or sequentially with respect to each other. In one or more embodiments during the cleaning operation the plasma gas P3 is flowed through the flow housing 171 simultaneously with the process gases P1 (the plasma gas P3 can be flowed with the process gases P1 or separately from the process gases P1), or before or after the flowing of the one or more process gases P1. The plasma PS1 may flow into the processing volume 136 before the processing gas P1 to pre clean the substrate 102. The plasma may flow into the processing volume 136 after the process gases P1 in order to clean the processing volume 136 after deposition operations. In one or more embodiments, the plasma gas P3 flows simultaneously with the process gases P1 through the flow housing 171. The plasma PS1 and the process gases P1 may flow into the processing volume 136 simultaneously where the plasma PS1 may assist in the deposition operation by facilitating activation of the process gas(es) P1 (e.g., by breaking bonds of the process gas(es) P1. The present disclosure contemplates that a voltage and/or a frequency of RF power 199 applied to the one or more RF coils 172 can be varied and/or pulsed. The frequency can involve a single frequency or multiple frequencies. The multiple frequencies can be combined.

The processing chamber 100 includes one or more sensor devices 195, 196, 197, 198 (e.g., metrology sensors, and/or temperature sensors) configured to measure parameter(s) (e.g., temperature(s)) within the processing chamber 100 and/or metrology parameter(s) of the substrate 102). In one or more embodiments, the one or more sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, the one or more sensor devices 195, 196, 197, 198 each include a sensor that includes one or more of silicon (Si), carbon (C), gallium (Ga), and/or nitrogen (N). In one or more embodiments, the one or more sensor devices 195, 196, 197, 198 each include a silicon sensor, a silicon carbide (SiC) sensor, and/or a gallium nitride (GaN) sensor. In one or more embodiments, one or more of the sensor devices 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature. For example, one or more of the sensor devices 195, 196, 197, 198 can measure one or more gas parameters and/or one or more plasma parameters (such as ion density, electron temperature, electron density, ion energy and angle distribution, enthalpy, radical density, and/or absorption). In one or more embodiments, one or more of the sensor devices 195, 196, 197, 198 include a residual gas analyzer, an optical emission spectrometer, an enthalpy probe, a Langmuir probe, Faraday cup, and/or an absorption spectrometer.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

The present disclosure contemplates that all sensor devices can be disposed above the plate 108 and/or on or adjacent to the lid 154. For example, the one or more lower sensor devices 195 can be omitted.

Each sensor device 195, 196, 197, 198, can be a single-wavelength sensor device or a multi-wavelength (such as dual-wavelength) sensor device. In one or more embodiments, the processing chamber 100 includes any one, any two, or any three of the four illustrated sensor devices 195, 196, 197, 198. In one or more embodiments, the processing chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

As shown, a controller 190 is in communication with the processing chamber 100 and is used to control processes and methods, such as the operations of the methods described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, the pre-heat ring 117, the substrate support 106, and/or the liners 111, 163. As an example, one or more sensor devices 195, 196, 197, 198 can measure temperatures of the substrate 102 and/or the pre-heat ring 117, and power to the one or more heat sources 141, 143 and/or the energy source 176 can be controlled based on the measured temperatures (e.g., using a feedback control). As described the one or more sensor devices can include, for example pyrometers. In one or more embodiments, one or more thermocouples (e.g., proximity thermocouples) can be used in addition to or in place of the pyrometers, and power to the one or more heat sources 141, 143 and/or the energy source 176 can be controlled based on the measured temperatures (e.g., using a feedback control).

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power supplied to the one or more heat sources 141, 143 and/or the one or more RF coils 172, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations (such as operations of the method 700) described herein. The instructions stored on the memory, when executed, cause one or more of the operations (such as operations of the method 700) described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to the one or more heat sources 141, 143 and/or the energy source 176, the deposition, the cleaning, the rotational position, the heating, and gas flow through the processing chamber 100 by providing an output to the controls for the sensor devices 195, 196, 197, 198, the one or more heat sources 141, 143 and/or the energy source 176, the process gas source 151, the purge gas source 162, the motion assembly 121, and/or the exhaust pump 157.

During processing, in one or more embodiments, the substrate 102 is heated to a target temperature of 400 degrees Celsius or higher, or 600 degrees Celsius or less. In one or more embodiments, the target temperature for the substrate 102 is within a range of 380 degrees Celsius to 600 degrees Celsius, for example 400 degrees Celsius to 500 degrees Celsius. In one or more embodiments, the target temperature for the substrate 102 is less than 500 degrees Celsius. In one or more embodiments, the target temperature for the substrate 102 is 400 degrees Celsius or less, such as less than 200 degrees Celsius (for example about 150 degrees Celsius).

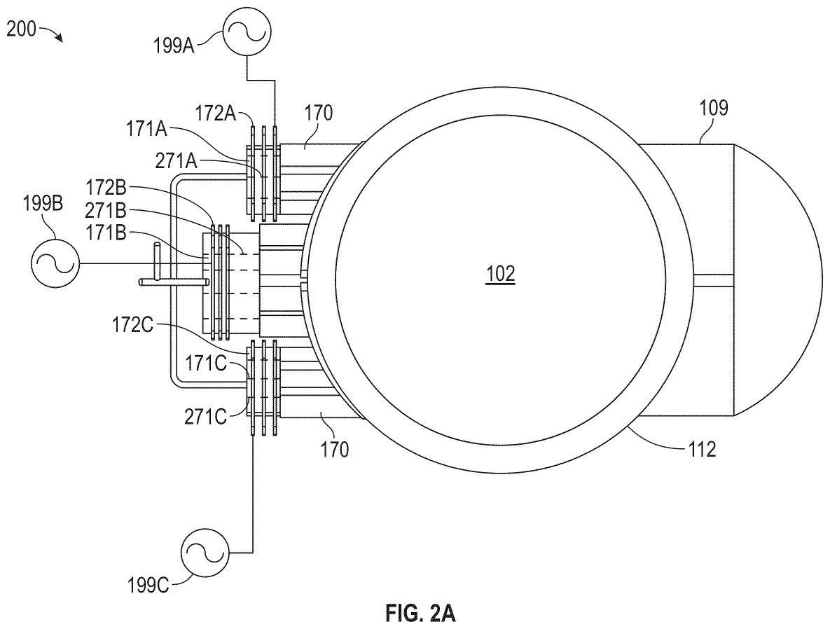

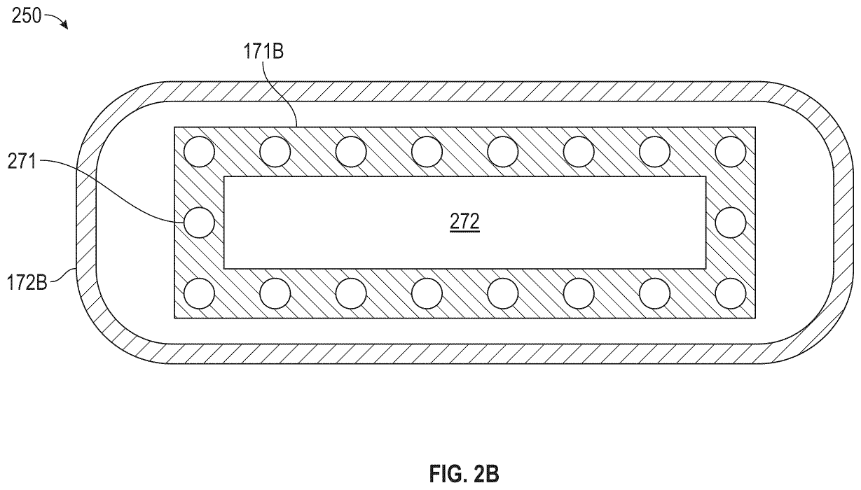

FIG. 2A is a schematic partial top cross-sectional view of a processing chamber 200 according to one or more embodiments. Processing chamber 200 is similar to processing chamber 100 shown in FIG. 1 and includes one or more aspects, features, components, operations, and/or properties thereof.

The processing chamber 200 includes a plurality of flow housings 171A, 171B, 171C. Each flow housing 171A, 171B, 171C includes one or more RF coils 172A, 172B, 172C disposed at least partially around the respective flow housing 171A, 171B, 171C. In one or more embodiments, the flow housings 171A, 171B, 171C respectively include a plurality of cooling channels 271A, 271B, 271C. One or more flow channels 170 respectively connect the flow housing 171A, 171B, 171C to the processing volume 136.

In one or more embodiments the RF coils 172 around flow housing are controlled independently by powering the respective RF coils 172 independently of each other. One or more power sources 199A, 199B, 199C are connected to the RF coils 172A, 172B, 172C, and the power sources 199A, 199B, 199C can respectively control the power applied to the individual RF coils 172A, 172B, and 172C.

FIG. 2B is a schematic side cross-sectional view of a flow housing assembly 250, according to one or more embodiments. The flow housing assembly 250 includes the flow housing 171B which contains an internal volume 272 in order to allow the gases to pass through. Cooling channels 271 are disposed in (e.g., are formed in one or more sidewalls of) the flow housing 171 to reduce or eliminate overheating of the flow housing 171. The cooling channels 271 may flow any cooling fluids to cool plasma apparatuses, such as water and/or air. The RF coils 172B surround the flow housing 171 in order to apply a voltage to the gas and ignite the gas into a plasma.

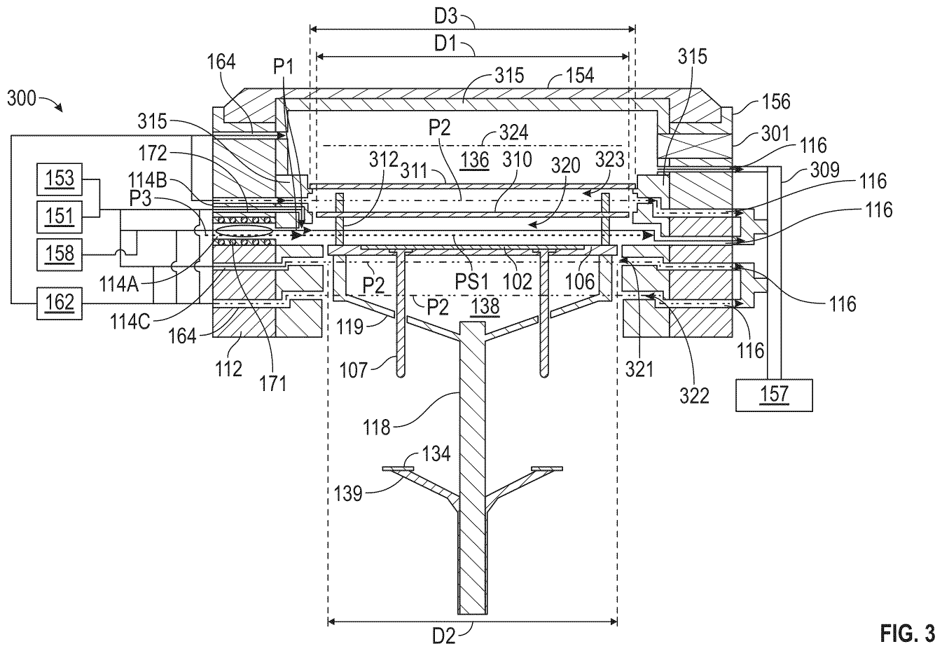

FIG. 3 is a schematic side cross-sectional view of a processing chamber 300, according to one or more embodiments.

The processing chamber 300 is similar to the processing chamber 100 shown in FIG. 1, and includes one or more aspects, features, components, operations, and/or properties thereof.

The processing chamber 300 includes a door 301 (e.g., a slit valve), a first plate 310, a second plate 311, and one or more liners 315. The door 301 is disposed above the gas exhaust outlets 116. The one or more liners 315 may include a single liner, or a plurality of liners stacked on each other. The first plate 310 has an outer dimension D1 that is greater than an outer dimension D2 of the substrate support 106. The second plate 311 has an outer dimension D3 that is greater than the outer dimension D1 of the first plate 310. The first plate 310 and the second plate 311 are made of an opaque material (such as white quartz, black quartz, silicon carbide, and/or graphite coated with silicon carbide). In one or more embodiments, the first plate 310 and/or the second plate 311 have a solid cross section across the respective outer dimensions D1, D3. In one or more embodiments, the second plate 311 is opaque and the upper heat sources 141 are omitted while the lower heat sources 143 are included in FIG. 3. In one or more embodiments, the second plate 311 is transparent and the upper and lower heat sources 141, 143 are included in FIG. 3. The second plate 311 may include at least one reflective outer surface, such as a reflective lower surface facing the first plate 310. In one or more embodiments, the at least one reflective outer surface has a reflectivity greater than about 90%, such as greater than about 98% for wavelengths of about 150 nm or higher, such as 150 nm to about 15000 nm, such as about 700 nm to about 15000 nm, about 700 nm to 1000 nm, or about 1000 nm to about 15000 nm. In one or more embodiments, the at least one reflective outer surface has a reflectivity greater than about 90%, such as greater than about 98% for wavelengths in the infrared range and/or the ultraviolet range. A plurality of spacers 312 are disposed on the top surface of the substrate support 106 and the first plate 310. The spacers 312 can include, for example, sleeves and/or rods. The plurality of spacers 312 help to support and raise or lower the first plate 310 and the second plate 311 when the substrate support 106 is raised or lowered. When the substrate support 106 is raised the plurality of spacers 312 disposed on the substrate support 106 can contact the bottom surface of the first plate 310 to engage and raise the first plate 311. The raising will then cause the first plate 310 to be raised along with the substrate support 106. The plurality of spacers 312 disposed on the top surface of the first plate 310 will then come into contact with the bottom surface of the second plate 311. Continued raising will cause the second plate 311 to raise with the first plate 310 when the substrate support 106 is raised.

The present disclosure contemplates that plasma-assisted process gas(es) P1 can flow from the side of the substrate 102, and process gas(es) P1 can flow from the side of the substrate 102 while the plasma is omitted. The present disclosure also contemplates that the plasma-assisted process gas(es) P1 can flow from the side of the substrate 102, and process gas(es) P1 can flow from above the substrate 102 while the plasma is omitted.

In one or more embodiments, the processing chamber 300 includes the flow housing 171 and the one or more RF coils 172 as previously described. The flow housing 171 may be disposed outwardly of the flow module 112 as depicted in the process chamber 100 in FIG. 1, or the flow housing 171 may be disposed at least partially inside of the flow module 112 as depicted process chamber 300. The RF coils 172 may be disposed around the outside of the flow housing 171 as depicted in process chamber 100 in FIG. 1, or the RF coils 172 may be disposed inside of (e.g., embedded in one or more sidewalls of) the flow housing 171 as depicted for the process chamber 300 in FIG. 3.

FIG. 3 depicts the process chamber 300 in a position configured for a deposition process. During the deposition process, a process gas P1 may flow from the process gas supply 151. The process gas P1 is flowed through the flow housing 171 and the gas inlet 114A into a first flow level 320. In one or more embodiments the process gas P1 flows through a second gas inlet 114B to circumvent the flow housing 171, in addition to or in place of flowing through the gas inlet 114A. As an example, process gas(es) that are activated without plasma assistance can flow through the gas inlet 114A and over the substrate 102. A third plate can be disposed to at least partially fluidly isolate gas flowing through the second gas inlet 114B from gas flowing through the gas inlet 114A. The third plate can include one or more aspects, features, components, operations, and/or properties of the first plate 310. The third plate can have a smaller outer dimension than the outer dimension D1. During the deposition process the substrate support 106 is positioned so that the substrate 102 aligned with the first flow level 320. In one or more embodiments a plasma gas P3 flows simultaneously from a plasma gas supply 158 through the flow housing 171, where the plasma gas P3 is ignited by the one or more RF coils 172. The plasma PS1 then flows to the first flow 320 level simultaneously with the process gas P1, in order to assist the process gas P1 in the deposition process. The process gas P1 and the plasma PS1 then flow to the gas exhaust outlet 116, and out of the processing volume 136 through the common exhaust 309.

In one or more embodiments, during the deposition process, one or more purge gases P2 flow from the purge gas supply 162 through the purge gas inlets 164 and a third gas inlet 114C to a second flow level 321, third flow level 322, fourth flow level 323, and fifth flow level. The purge gases P2 may help maintain pressure throughout the process chamber 300 to facilitate preventing the plasma and process gases from leaking from the first flow level 320 to other areas within the process chamber 300. The purge gases P2 then flows through the plurality gas exhaust outlets 116 into the common exhaust 309.

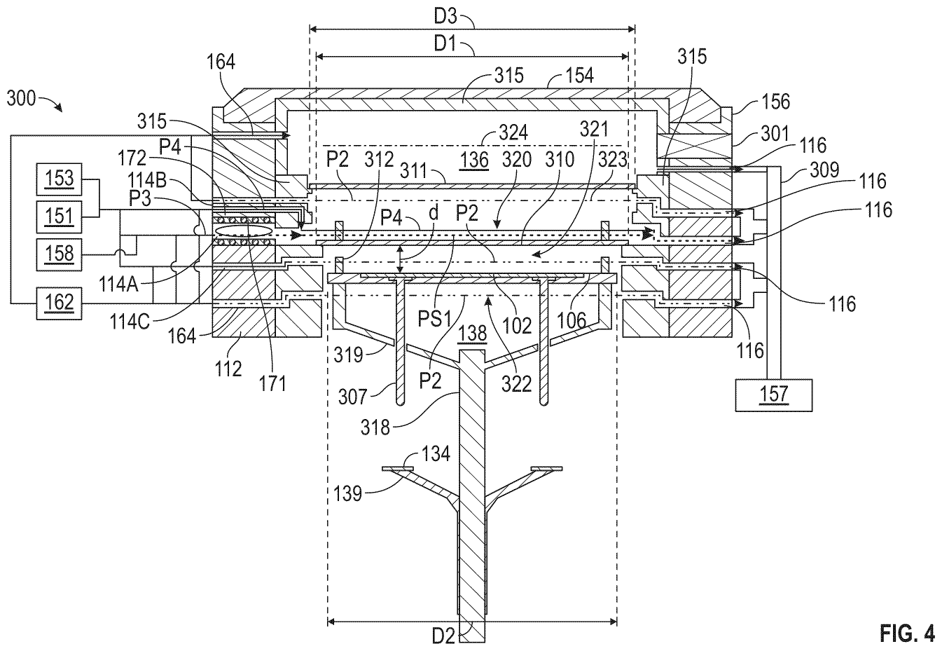

FIG. 4 depicts the process chamber 300 during a cleaning process. At the cleaning process the substrate support 106 is lowered so that the substrate 102 is aligned with the second flow level 321. As the substrate support 106 is lowered, both the first plate 310 and the second plate 311 are lowered until the bottom surface of the second plate 311 contacts at least one of the one or more liners 315. The second plate 311 contacts at least one of the one or more liners 315 because the second plate has the larger outer dimension than both the substrate support 106 and the first plate 310. The first plate 310 is then lowered until the bottom surface of the first plate 310 contacts at least one of the one or more liners 315 due to the first plate having a larger outer dimension than the substrate support 106. The first plate 310 resting on the one or more liners 315 stops the first plate 310 from being lowered further with the substrate support 106. The first plate 310 is positioned on the one or more liners 315 so that the first plate 310 is aligned with the first flow level 320. The substrate support 106 is then lowered so that the substrate 102 is aligned with the second flow level 321. A distance D within a range of about 8 mm to about 70 mm separates the top surface of the substrate support 106 and the bottom surface of the first plate 320.

FIG. 4 depicts the process chamber 300 in a position configured for a cleaning process. In one or more embodiments during the cleaning process a cleaning gas P4 (or an etchant gas) may flow from the cleaning gas supply 153. The cleaning gas P4 is flowed through the flow housing 171 and the gas inlet 114A into a first flow level 320. In more than one embodiments, the cleaning gas P4 flows through the second gas inlet 114B, in addition to or in place of flowing through the gas inlet 114A. During the cleaning process the first plate 310 is aligned with the first flow level 320. In one or more embodiments a plasma gas P3 flows simultaneously from a plasma gas supply 158 through the flow housing 171, where the plasma gas P3 is ignited into the plasma PS1 by the one or more RF coils 172. The plasma PS1 then flows to the first flow 320 level along with the cleaning gas P4, in order to assist the cleaning gas P4 in the cleaning process. The cleaning gas P4 and the plasma PS1 then flow to the gas exhaust outlet 116, and out of the processing volume 136 through the common exhaust 309. In one or more embodiments the cleaning gas P4 is flowed to the first flow level while the plasma PS1 is omitted. In one or more embodiments the plasma PS1 is flowed to the first flow level while the cleaning gas P4 is omitted.

In one or more embodiments, during the cleaning process, one or more purge gases P2 flow from the purge gas supply 162 through the purge gas inlets gas inlets 164 and a third gas inlet 114C to the second flow level 321, third flow level 322, fourth flow level 323, and fifth flow level. The purge gases P2 may help maintain pressure throughout the process chamber 300 to ensure that the plasma PS1 and cleaning gas P4 do not leak from the first flow level 320 to other areas within the process chamber 300. The purge gases P3 then flow through the plurality gas exhaust outlets 116 into the common exhaust 309.

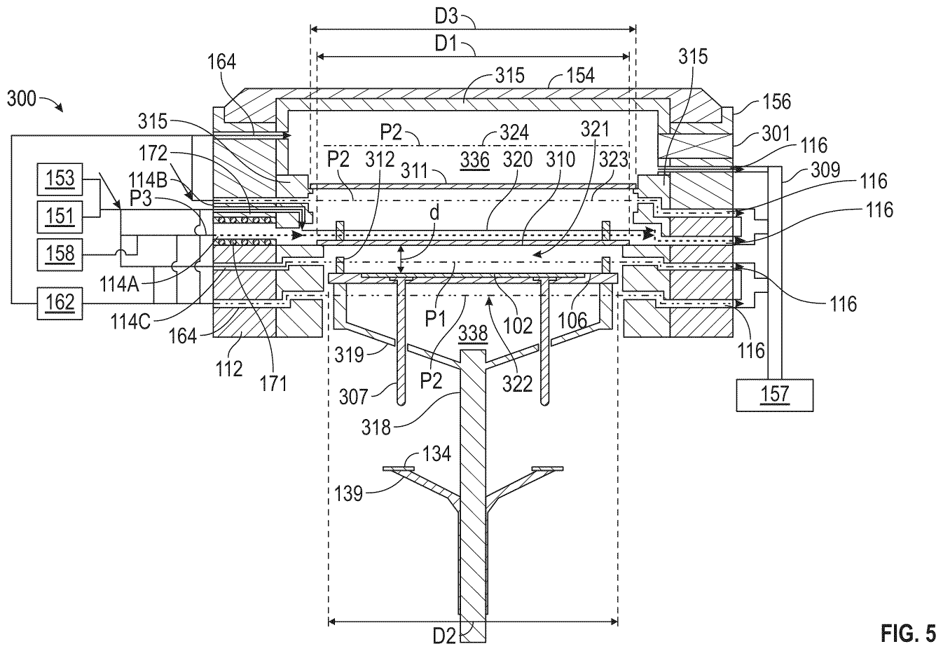

FIG. 5 depicts the processing chamber 300 in a position configured for a second deposition process. In one or more embodiments, during the second deposition process a process gas P1 may flow from the process gas supply 151. The process gas P1 is flowed through the third gas inlet 114C into the second flow level 321. During the deposition process the substrate support 106 is positioned so that the substrate 102 is in line with the first flow level 321. The process gas P1 flows across the substrate 102 to the gas exhaust outlet 116, and out of the processing volume 136 through the common exhaust 309.

In one or more embodiments, during the second deposition process, one or more purge gases P2 flow from the purge gas supply 162 through the purge gas inlets gas inlets 164, the second gas inlet 114B, and the gas inlet 114A with the flow housing 171 to the first flow level 320, third flow level 322, fourth flow level 323, and fifth flow level. The purge gases P2 may help maintain pressure throughout the process chamber 300 to facilitate preventing the process gas P1 from leaking from the first flow level 320 to other areas within the process chamber 300. The purge gases P2 then flows through the plurality of gas exhaust outlets 116 and into the common exhaust 309. The process gas P1 of FIG. 5 can be replaced with the cleaning (or etchant) gas P4, such as to etch the substrate 107. For example, the operations of FIG. 5 can etch film deposited on the substrate 102 at FIG. 3, or the operations of FIG. 5 can pre-clean the substrate 102 prior to the deposition operations of FIG. 3.

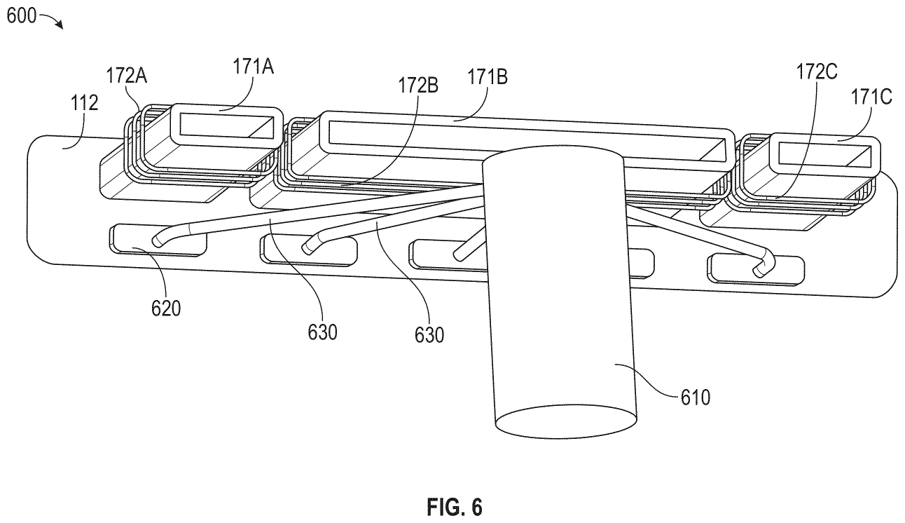

FIG. 6 is a schematic perspective view of a side of a processing chamber 600, according to one or more embodiments. The processing chamber 600 is similar to the processing chamber 100 shown in FIG. 1, and includes one or more aspects, features, components, operations, and/or properties thereof.

The processing chamber 600 includes a remote plasma source (RPS) 610 which is fluidly coupled to a plurality of plasma connectors 630 that fluidly connect to a plurality of plasma inlets 620 coupled to the flow module 112. This allows for a plasma to flow from the RPS 610 into the processing chamber 600 to assist with the deposition and/or cleaning process. The plasma originating from the RPS 610 may be flowed separately or in conjunction with the plasma formed in the flow housing 171 as described above. The flow housings 171A, 171B, and 171C and the plasma connectors 630 facilitate supplying plasma in a plurality of zones for the respective flow levels 320 321.

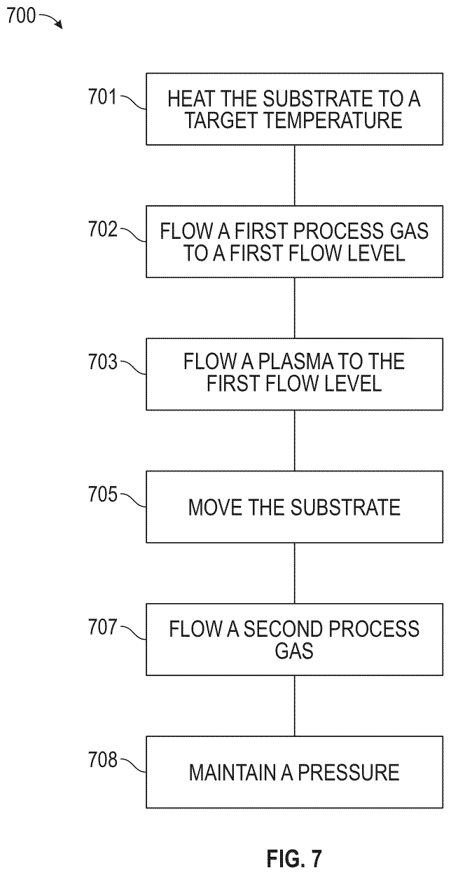

FIG. 7 is a schematic block diagram view of a method 700 of substrate processing for semiconductor manufacturing, according to one or more embodiments.

Operation 701 of the method 700 includes heating a substrate positioned on a substrate support of a processing chamber. The substrate is disposed in a processing volume of the processing chamber. The substrate can be heated from both sides or from one side of the substrate. The heating includes heating the substrate to a target temperature. In one or more embodiments, the target temperature is less than 500 degrees Celsius. In one or more embodiments, the target temperature is 400 degrees Celsius or less.

Operation 702 includes flowing a first process gas to a first flow level. The first process gas flows over the substrate aligned with the first flow level.

Operation 703 includes supplying a plasma to a first flow level in a processing volume of the processing chamber. The plasma can be generated outside of the processing volume and then flowed into the processing volume. For example a plasma precursor gas can flow through the flow housing 171 as described in FIG. 1. A power may then be applied to an RF coil 172 disposed at least partially around (e.g., surrounding) the flow housing 171 to generate the plasma. The generated plasma is then flowed to the first flow level. In one or more embodiments, the plasma of operation 703 is supplied during the flowing of the first process gas of operation 702, and the plasma flows over the substrate. In one or more embodiments, the plasma of operation 703 is supplied before or after the flowing of the first process gas of operation 702.

Operation 705 includes moving the substrate. The substrate can be moved, for example, by lifting or lowering the substrate support.

Operation 707 includes flowing a second process gas. The second process gas can be supplied to the first flow level or a second flow level that is aligned with the substrate after the moving of operation 705.

Operation 708 includes maintaining the processing volume at a pressure. In one or more embodiments, the pressure is maintained to be less than 60 Torr, such as within a range of 0 Torr to 30 Torr. In one or more embodiments, the pressure is maintained to be less than 1 Torr, such as within a range of 0 Torr to 5 m Torr.

Benefits of the present disclosure include reliable gas activation (such as at relatively low processing temperatures); adjustability of gas activation; modularity of using plasma operations and epitaxial deposition operations in a single chamber; modularity in chamber application; more uniform gas activation; temperature uniformity (e.g., temperature uniformity in an outer region of the substrate); reduced gas consumption and gas waste; increased growth rates; and more uniform film growth and/or dopant concentration. As an example, ions and/or radicals can be used to activate gases for processing in addition to or in place of electromagnetic radiation (such as infrared radiation and/or ultraviolet radiation).

Benefits also include enhanced device performance; reduced or eliminated occurrences of unintended dopant diffusions; efficient processing; and increased throughput. As an example, the gas activation is facilitated for substrate target temperatures less than 500 degrees Celsius, such as target temperatures within a range of 380 degrees to 500 degrees Celsius. For example, gas can be activated for processing operations when the substrate is at about 400 degrees Celsius.

It is contemplated that one or more aspects disclosed herein may be combined. As an example, one or more aspects, features, components, operations and/or properties of the processing chamber 100; the flow module 112, the flow housing(s) 171A, 171B, 171C, the RF coil(s) 172A, 172B, 172C, the plasma gas source 158, the cooling channels 271, the processing chamber 300, the first plate 310, the second plate 311, the liner(s) 315, the first flow level 320, the second flow level 321, the processing chamber 600, the RPS 610, and/or the method 700 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for semiconductor manufacturing, comprising:
one or more sidewalls;
a window at least partially defining a processing volume;
a substrate support disposed in the processing volume;
one or more heat sources operable to heat the processing volume; and
one or more radio frequency (RF) coils disposed at least partially around the flow housing.

2. The processing chamber of claim 1, wherein the flow housing comprises one or more cooling channels.

3. The processing chamber of claim 1, wherein the flow housing comprises quartz or silicon carbide.

4. The processing chamber of claim 1, further comprising a second flow housing and one or more second RF coils disposed at least partially around the flow housing.

5. The processing chamber of claim 4, wherein a first power supplied to the one or more RF coils is independently controllable relative to a second power supplied to the one or more second RF coils.

6. The processing chamber of claim 1, further comprising a third flow housing and one or more third RF coils disposed at least partially around the third flow housing.

7. A chamber kit applicable for semiconductor manufacturing, comprising:
a substrate support having a first outer dimension;
a first plate having a second outer dimension that is larger than the first outer dimension; and
a second plate having a third outer dimension that is larger than the second outer dimension.

8. The chamber kit of claim 7, wherein the first plate and the second plate respectively comprise quartz or silicon carbide.

9. The chamber kit of claim 7, further comprising a flow housing and one or more radio frequency (RF) coils.

10. The chamber kit of claim 9, wherein the flow housing comprises one or more cooling channels.

11. The chamber kit of claim 9, further comprising a second flow housing and one or more second RF coils disposed at least partially around the second flow housing.

12. The chamber kit of claim 7, wherein the first plate has a solid cross section across the second outer dimension.

13. The chamber kit of claim 7, wherein the second plate has a solid cross section across the third outer dimension.

14. The chamber kit of claim 7, wherein the second plate comprises at least one reflective outer surface.

15. The chamber kit of claim 7, wherein first plate and the second plate respectively comprise at least one opaque outer surface.

16. A method of substrate processing, comprising:
heating a substrate on a substrate support to a target temperature;
flowing a first process gas to a first flow level aligning with the substrate; and
flowing a plasma to the first flow level.

17. The method of claim 16, wherein the plasma flows to the first flow level simultaneously with the flowing of the first process gas.

18. The method of claim 16, wherein:
the flowing of the first process gas comprises flowing the first process gas through a flow housing; and
the flowing of the plasma comprises:
flowing a plasma gas through a flow housing, and
applying a power to the plasma gas to generate the plasma.

19. The method of claim 16, further comprising:
lowering the substrate support; and
flowing a second process gas to the first flow level.

20. The method of claim 16, further comprising:
lowering the substrate support,
flowing a second process gas to a second flow level aligning with the substrate.
